(19) United States
(12) Patent Application Publication
(10) Pub. No.: US 2008/0018325 A1
(43) Pub. Date: Jan. 24, 2008

(54) APPARATUS AND METHOD FOR MEASURING AN OUTPUT POWER OF A POWER SUPPLY

(75) Inventors: Xiang Yu, Shenzhen (CN); Mao-Chun Wang, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,285

(22) Filed: Jul. 21, 2006

(51) Int. Cl. G01R 7/00

(52) U.S. Cl. 324/142

(57) ABSTRACT

An assembly includes a power supply and a meter. The power supply has a cable with a plurality of pins providing different voltages to a corresponding plurality of receiving pins. Each pin is connected to one of the receiving pins by a resistor of known value. The meter measures voltages of all of the resistors and all of the receiving pins simultaneously. Current passing through each of the resistors is calculated as a quotient of a voltage measured across each resistor and the known value of the resistor. Power delivered to each receiving pin is calculated as a product of the calculated current through the corresponding resistor and a voltage measured at the receiving pin with respect to ground. The total output power of the power supply is the sum of the powers calculated for each of the receiving pins.

### FIELD OF THE INVENTION

The present invention relates to measuring power consumption of a computer, and more particularly to an/a apparatus and method for measuring an output power of a power supply.

### DESCRIPTION OF RELATED ART

Nowadays, energy conservation is so important, that greater efficiency of energy use is sought. Computers are in widespread use, and consume a great deal of energy. Computers are powered by power supplies, which convert alternating current into direct current required by the computers. It is crucial to improve the efficiency of power supplies as a way to reduce power consumption of computers. For improving the efficiency of power supplies, it is important to precisely measure input and output power of the power supplies.

However, power supplies may provide a plurality of different voltage levels, such as +12V, +5V, +3.3V, −12V, to the components in a computer, such as CPU, motherboard, and so on. These voltages are provided through different pins of the cables that transfer power from a power supply to the components. There are different voltages and currents on different pins. It can be difficult to measure all of the pins synchronously, and the output power of the power system can be difficult to calculate.

It is therefore desirable to find a measuring apparatus and method which overcomes the above mentioned problems.

### SUMMARY OF THE INVENTION

In one aspect, an electrical assembly includes a power supply and a meter. The power supply has a cable with a plurality of pins providing different voltages to a corresponding plurality of receiving pins. Each pin is connected to one of the receiving pins by a resistor of known value. The meter measures voltages across all of the resistors and at all of the receiving pins simultaneously. Current passing through each of the resistors is calculated as a quotient of a voltage measured across each resistor and the known value of the resistor. Power delivered to each receiving pin is calculated as a product of the calculated current through the corresponding resistor and a voltage measured at the receiving pin with respect to ground. The total output power of the power supply is the sum of the powers calculated for each of the receiving pins.

In another aspect, a method for measuring an output power of a power supply, comprising following steps:

providing a circuit board, the circuit board having a connector connected to the power supply and another connector connected to a power consumption component, the connector comprising different pins providing different voltages, and the another connector comprising a plurality of receiving pins corresponding to each of the pins, the circuit board having a corresponding plurality of resistors, each pin of the connector connected to a corresponding receiving pin of the another connector via one of the plurality of resistors;
electrically connecting a meter to the circuit board in a manner so as to measure voltages across all of the resistors and at all of the receiving pins simultaneously;
obtaining a current passing through one of the resistors by measuring a voltage across the resistor and dividing by a value of the resistor;
obtaining a power delivered to each of the receiving pins as a product of voltage measured at the corresponding receiving pin with respect to ground and the obtained current through the corresponding resistor; and
summing up the powers delivered to each of the receiving pins, which represents a total output power of the power supply.

In still another aspect, an apparatus for measuring an output power of a power supply includes a circuit board and a meter. The circuit board has a connector configured so as to connect to the power supply and another connector configured so as to connect to a power consumption component. The connector includes different pins providing different voltages. The another connector includes a plurality of receiving pins corresponding to each of the different pins. The circuit board has a corresponding plurality of resistors. Each pin of the connector is connected to a corresponding receiving pin of the another connector via one of the resistors. The meter has a plurality of first and second channels. Each of the first channels is configured so as to be electrically connected to opposite ends of one of the resistors for measuring a voltage across the one of the resistors. Each of the second channels is configured so as to be electrically connected to one corresponding receiving pin connected to the one of the resistors for measuring a voltage at the one corresponding receiving pin connected to the one of the resistors.

Other advantages and novel features will be drawn from the following detailed description of preferred embodiments with attached drawings, in which:

### BRIEF DESCRIPTION OF THE DRAWINGS

FIG. 1 is a schematic view of a measuring apparatus for measuring an output power of a power supply provided to a motherboard and a CPU, which includes a circuit board, and a meter; and

FIG. 2 is a circuit diagram of the board and the meter of FIG. 1.

### DETAILED DESCRIPTION OF THE INVENTION

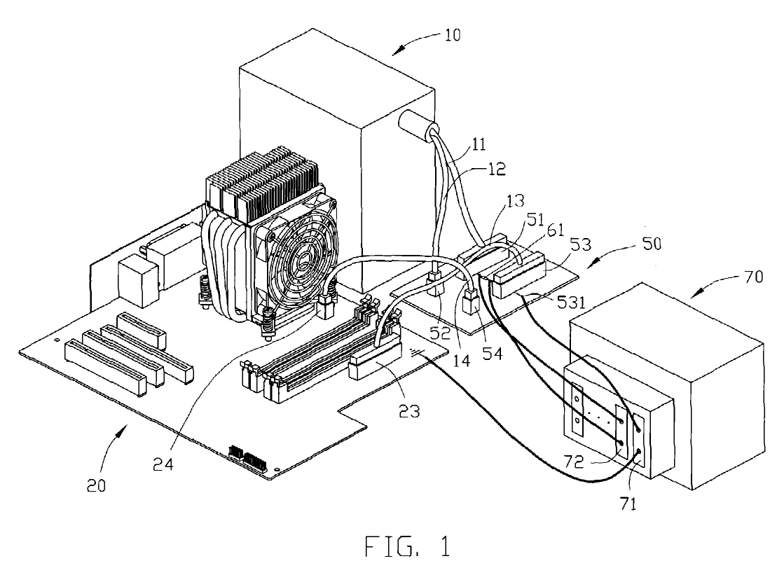

Referring to FIG. 1, a measuring apparatus for measuring an output power of a power supply 10 provided to a motherboard 20 and a CPU (not shown) includes a circuit board 50 and a meter 70.

The power supply 10 has two cables 111 and 12 for providing power to the motherboard 20 and CPU respectively. The motherboard 20 includes a motherboard power receptacle 23 and a CPU power receptacle 24.

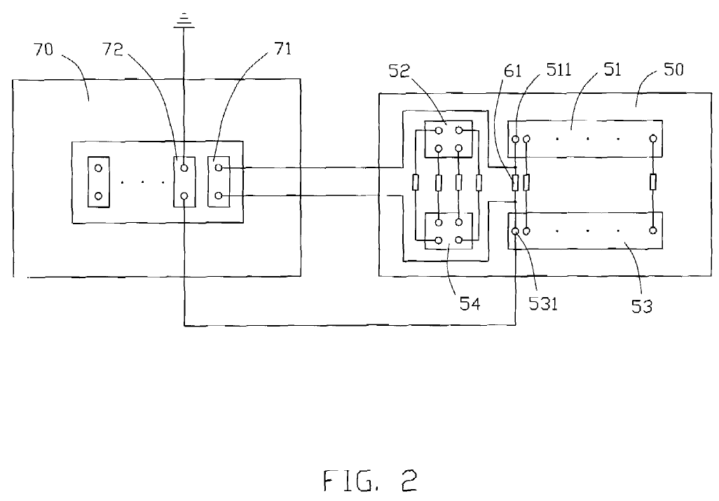

Referring to FIGS. 1 and 2, the circuit board 50 includes a first connector 51, a second connector 52, a third connector 53, and a fourth connector 54. The cable 111 is connected to the first connector 51, and the cable 12 is connected to the second connector 52. A cable 13 connects the third connector 53 of the circuit board 50 to the motherboard power receptacle 23. A cable 14 connects the fourth connector 54 of the circuit board 50 to the CPU power receptacle 24.

The first connector 51 and the third connector 53 are same type of connectors each having a plurality of pins. Each pin of the first connector 51 is connected to a corresponding pin of the third connector 53 via a small value resistor, such as 1 milliohm. For example, a first pin 511 of the first connector 51 is connected to a first receiving pin 531 of the third connector via a resistor 61. The second connector 52 and the fourth connector 54 are same type of connectors each also having a plurality of pins. Each pin of the second connector 52 is connected to a corresponding pin of the fourth connector 54 via a resistor, as was done between the first connector 51 and the third connector 53.

The meter 70 can be any meter capable of measuring different voltages of a plurality of components simultaneously, such as a hybrid recorder produced by Yokogawa Electric Corporation or other similar apparatus. The meter 70 includes a plurality of channels with each channel adapted for measuring a voltage of a component. As depicted in FIG. 1, the meter 70 includes a first channel 71 and a second channel 72, and so on. Each channel has two terminals. The meter 70 is able to record the measured voltages in a set time cycle.

FIGS. 1 and 2 show an output power of the first pin 511 of the first connector 51, which corresponds to a pin of the power supply 10, being measured. The two terminals of the first channel 71 are connected to opposite ends of the resistor 61 to measure a voltage across the resistor 61 for calculating current passing through the resistor 61. Meanwhile, one terminal of the second channel 72 is connected to the first receiving pin 531 of the third connector 53, which is connected to one end of the resistor 61, and the other terminal is connected to ground. Therefore, a voltage of the first receiving pin 531 of the third connector 53 is measured with respect to ground. Thus, with current and voltage delivered to that point by the power supply 10 known, output power is easily calculated. Because the resistance of the resistor 61 is very small, power dissipated by the resistor can be ignored.

Because the meter 70 has multiple channels, it is convenient to get output powers of all of the pins at a same point in time. Therefore, the total output power of the power supply 10 at any given point in time can be calculated merely by adding the output powers of all of the pins.

Furthermore, the meter 70 can record the measured values in a set time cycle, such as 2 seconds, so it is able to get output powers of the power supply 10 at different time points in a certain time period, which is useful for analyzing the performance of the power supply 10.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electrical assembly, comprising:
a power supply, the power supply having a cable with a plurality of pins providing different voltages to a corresponding plurality of receiving pins, each pin being connected to the corresponding receiving pin by a resistor of known value; and
a meter capable of measuring different voltages of a plurality of components, the meter being configured for measuring voltages across all of the resistors and at all of the receiving pins simultaneously.

2. The electrical assembly as described in claim 1, wherein the meter is a hybrid recorder.

3. The electrical assembly as described in claim 2, wherein the hybrid recorder is able to record the measured values in a set time cycle.

4. The electrical assembly as described in claim 1, wherein the meter includes a plurality of channels each configured for measuring one of a voltage across one resistor and a voltage at a corresponding receiving pin connected to the one resistor.

5. The electrical assembly as described in claim 4, wherein the plurality of channels includes a first channel and a second channel, each of the first and second channels includes first and second terminals, the first and second terminals of the first channel are electrically connected to opposite two ends of the one resistor for measuring the voltage across the one resistor, the first terminal of the second channel is electrically connected to corresponding receiving pin, and the second terminal of the second channel is connected to ground for measuring the voltage at the corresponding receiving pin with respect to ground.

6. The electrical assembly as described in claim 1, further comprising a circuit board on which a connector is connected to the cable and another connector is connected to a power consumption component, wherein the connector and the another connector are the same type of connectors, the cable is connected to the connector which provides the plurality of pins, the plurality of receiving pins is formed in the another connector.

7. A method for measuring an output power of a power supply, comprising steps of:
providing a circuit board, the circuit board having a connector connected to the power supply and another connector connected to a power consumption component, the connector comprising different pins providing different voltages, and the another connector comprising a plurality of receiving pins corresponding to each of the pins, the circuit board having a corresponding plurality of resistors, each pin of the connector connected to a corresponding receiving pin of the another connector via one of the plurality of resistors;
electrically connecting a meter to the circuit board in a manner so as to measure voltages across all of the resistors and at all of the receiving pins simultaneously;
obtaining a current passing through one of the resistors by measuring a voltage across the resistor and dividing by a value of the resistor;
obtaining a power delivered to each of the receiving pins as a product of voltage measured at the corresponding receiving pin with respect to ground and the obtained current through the corresponding resistor; and
summing up the powers delivered to each of the receiving pins, which represents a total output power of the power supply.

8. The method as described in claim 7, wherein the meter is a hybrid recorder.

9. The method as described in claim 8, wherein the hybrid recorder is able to record the measured values in a set time cycle.

10. The method as described in claim 7, wherein the connector and the another connector are the same type connectors.

11. The method as described in claim 7, wherein the meter includes a plurality of channels each configured for measuring one of a voltage across one resistor and a voltage at a corresponding receiving pin connected to the one resistor.

12. The method as described in claim 11, wherein the plurality of channels includes a first channel and a second channel, each of the first and second channels includes first and second terminals, the first and second terminals of the first channel are electrically connected to opposite two ends of the one resistor for measuring the voltage across the one resistor, the first terminal of the second channel is electrically connected to corresponding receiving pin, and the second terminal of the second channel is connected to ground for measuring the voltage at the corresponding receiving pin with respect to ground.

13. An apparatus for measuring an output power of a power supply, the apparatus comprising:
a circuit board having a connector configured so as to connect to the power supply and another connector configured so as to connect to a power consumption component, the connector comprising different pins providing different voltages, the another connector comprising a plurality of receiving pins corresponding to each of the different pins, the circuit board having a corresponding plurality of resistors, each pin of the connector connected to a corresponding receiving pin of the another connector via one of the resistors; and
a meter having a plurality of first and second channels, each of the first channels being configured so as to be electrically connected to opposite ends of one of the resistors for measuring a voltage across the one of the resistors, each of the second channels being configured so as to be electrically connected to one corresponding receiving pin connected to the one of the resistors for measuring a voltage at the one corresponding receiving pin connected to the one of the resistors.

14. The apparatus according to claim 13, wherein each of the second channels has two terminals with one terminal connected to the one receiving pin and the other terminal connected to ground.
